(19) United States
(12) Patent Application Publication
(10) Pub. No.: US 2013/0092961 A1
(43) Pub. Date: Apr. 18, 2013

(54) LIGHT EMITTING DEVICE MODULE

(71) Applicant: SAMSUNG ELECTRONICS CO., LTD., Suwon-si (KR)

(72) Inventors: Hyung Kun KIM, Suwon-si (KR); Sung Kyong OH, Suwon-si (KR)

(73) Assignee: SAMSUNG ELECTRONICS CO., LTD., Suwon-si (KR)

(21) Appl. No.: 13/651,839

(22) Filed: Oct. 15, 2012

(30) Foreign Application Priority Data
Oct. 14, 2011 (KR) 10-2011-0105343

(51) Int. Cl. H01L 33/50; H01L 33/60; H01L 27/15

(52) U.S. Cl. 257/88; 257/98; 257/E33.061; 257/E33.072; 257/E27.12

(57) ABSTRACT

According to example embodiments, a light emitting device (LED) module includes a substrate, a LED on the substrate, a first reflector on the substrate, and a phosphor structure contacting the first reflector. The first reflector may surround the LED from a plan view. The first reflector may have a width at a middle portion of the reflector that is smaller than a width at a bottom portion of the reflector. The LED module may obtain a desired view angle depending on various applications by adjusting a height of the first reflector and/or a difference between the height of first reflector and a height of a phosphor structure.

### CROSS-REFERENCE TO RELATED APPLICATION

This application claims priority under 35 U.S.C. §119 to Korean Patent Application No. 10-2011-0105343, filed on Oct. 14, 2011 in the Korean Intellectual Property Office, the entire disclosure of which is incorporated herein by reference.

### BACKGROUND

1. Field

Example embodiments relate to a light emitting device (LED) module, and more particularly, to an LED module that may obtain a desired view angle depending on various applications.

2. Description of the Related Art

A light emitting device (LED) may be a semi-conductor light emitting apparatus that emits light when a current flows. The LED may have features of a long life-span, a low power consumption, a fast response speed, an excellent initial operation. The LED may be applied to a lighting device, a headlight and a courtesy light of a car, an electronic display board, a backlight of a display device. The number of fields where a LED may be applied has increased.

The LED may be used as a light source of various colors. As the demand for a high power and high luminance LED, such as a white LED for lighting and the like, increases, research for improving the performance and reliability of an LED package is being conducted. To improve the performance of an LED product, an LED package that effectively extracts light, that has an excellent color purity, and that has a uniform property among products may be desired in addition to an LED with an excellent optical efficiency.

Phosphors may be disposed on a blue LED or an ultraviolet LED to obtain a white light using the LED. The white LED may color-transform a portion of light extracted from the blue LED or the ultraviolet LED, based on a combination of a red phosphor, a green phosphor, a blue phosphor, and a yellow phosphor, and may provide a while light by mixing the phosphors. In addition to efficiency, which may be an important factor for determining the performance of the white LED, a color uniformity may also be important.

A LED may be manufactured as a package or a module to be a product. The LED package may be manufactured by first mounting an LED chip on a lead frame or a ceramic substrate, mixing and applying phosphors suitable for a desired application, and molding a lens. Thereafter, the LED package may be cut into unit LED packages, and may be mounted on a printed circuit board (PCB) to be modularized.

A structure of mounting an LED package on a PCB to be modularized may reduce (and/or limit) miniaturization of an LED module, and may fail to decrease a manufacturing cost of the LED module due to a high rate of error while mounting is performed at least twice. Luminance and a color of the LED package may have a deviation due to a deviation in a wavelength and luminance of an LED, a manufacturing tolerance on a structure such as a lead frame, and a process tolerance on a phosphor coating process, a lens molding process, and the like.

Recently, a chip on board (COB) scheme in which an LED is mounted directly on a module substrate is being used to manufacture the LED as a module rather than as a package. The LED module manufactured through the COB scheme may reduce a cost for manufacturing a package, and enhance heat radiation efficiency by reducing a heat transfer path. Also, various attempts are being made to obtain a desired view angle, for example, by changing a shape of a lens when manufacturing a module through the COB scheme.

### SUMMARY

Herein, a light emitting device (LED) module that may have a view angle depending on various applications will be provided.

According to example embodiments, a light emitting device (LED) module includes a substrate, an LED on the substrate, a phosphor layer on the LED, and a first reflector surrounding the LED. The first reflector has an inclined inner plane. Here, a view angle of the LED may be adjusted (and/or affected) based on a difference between a height of the first reflector and a height of the phosphor layer.

In example embodiments, the inclined inner plane of the first reflector may have a curved surface.

In example embodiments, a height of the first reflector may be greater than a height of the phosphor layer.

In example embodiments, the phosphor layer may be formed by dispensing a phosphor resin on the LED.

In example embodiments, the LED may be connected to the substrate using one of a flip chip bonding scheme and a die bonding scheme.

In example embodiments, the first reflector may contact the phosphor layer and a width at a top portion of the first reflector may be smaller than a width at a bottom portion of the first reflector.

According to example embodiments, a light emitting device (LED) module includes a substrate, an LED on the substrate, a first reflector and a second reflector surrounding the LED from a plan view, and phosphor plate between the first reflector and the second reflector. The first reflector and the second reflector have inclined inner planes. Here, a view angle of the LED may be adjusted (and/or affected) based on a height of the third reflector.

In example embodiments, a gradient of the inner plane of the first reflector may be different from a gradient of the inner plane of the second reflector.

In example embodiments, the gradient of the inner plane of the first reflector may be less than the gradient of the inner plane of the second reflector.

In example embodiments, the inclined inner planes of the first reflector and the second reflector may have curved surfaces.

In example embodiments, the LED may be connected to the substrate using one of a flip chip bonding scheme and a die bonding scheme.

According to example embodiments, a light emitting device (LED) module includes a substrate, a LED on the substrate, a first reflector on the substrate, and a phosphor structure contacting the first reflector. The first reflector may surround the LED from a plan view. The first reflector may have a width at a middle portion of the reflector between an outer plane and an inclined inner plane that is smaller than a width at a bottom portion of the reflector between the outer plane and the inclined inner plane.

In example embodiments, the phosphor structure may be a phosphor layer on the LED, the phosphor layer may contact the inclined inner plane of the first reflector, a height of the phosphor layer may be less than the height of the first reflector, and the inclined inner plane of the first reflector may have a curved surface.

In example embodiments, a second reflector may be on the phosphor structure, and the second reflector may surround the LED from the plan view. The second reflector may have an inclined inner plane. A gradient of the inclined inner plane of the second reflector may be different from a gradient of the inclined inner plane of the first reflector.

In example embodiments, a plurality of the LEDs may be on the substrate, a plurality of the first reflectors may surround the plurality of LEDs from the plan view, respectively, and a plurality of the phosphor structure may contact the plurality of first reflectors, respectively.

In example embodiments, the LED may be connected to the substrate using one of a flip chip bonding scheme and a die bonding scheme.

### BRIEF DESCRIPTION OF THE DRAWINGS

The foregoing and/or other aspects, features, and advantages of example embodiments will become apparent and more readily appreciated from the following description of non-limiting embodiments, as illustrated in the accompanying drawings in which like reference characters refer to the same parts throughout the different views. The drawings are not necessarily to scale, emphasis instead being placed upon illustrating the principles of inventive concepts. In the drawings:

FIGS. 1A through 1C are cross-sectional views illustrating a light emitting device (LED) module according to example embodiments;

FIGS. 1D through 1E are a top view and a perspective view illustrating a light emitting device (LED) module according to example embodiments;

FIGS. 2A through 2C are cross-sectional views illustrating an LED module according to example embodiments;

FIGS. 3A and 3B are cross-sectional views illustrating an LED module according to example embodiments; and

FIG. 4 is a cross-sectional view of an LED in an LED module according to example embodiments.

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of inventive concepts to those of ordinary skill in the art. In the drawings, the thicknesses of layers and regions are exaggerated for clarity. Like reference numerals in the drawings denote like elements, and thus their description may be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

Throughout the specification, when it says that each of a layer, a side, a chip, and the like is formed “on” or “under” a layer, a side, a chip, and the like, the term “on” may include “directly on” and “indirectly on by interposing another element therebetween,” and the term “under” may include “directly under” and “indirectly under by interposing another element therebetween.” A standard for “on” or “under” of each element may be determined based on a corresponding drawing.

A size of each element in drawings may be exaggerated for ease of description, and may not indicate a size to actually be applied.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof. Expressions such as “at least one of,” when preceding a list of elements, modify the entire list of elements and do not modify the individual elements of the list.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

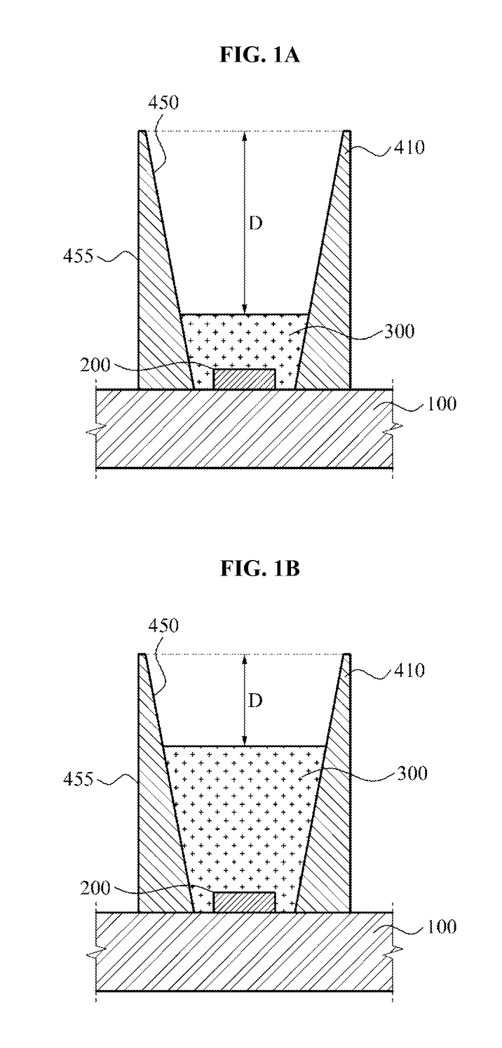

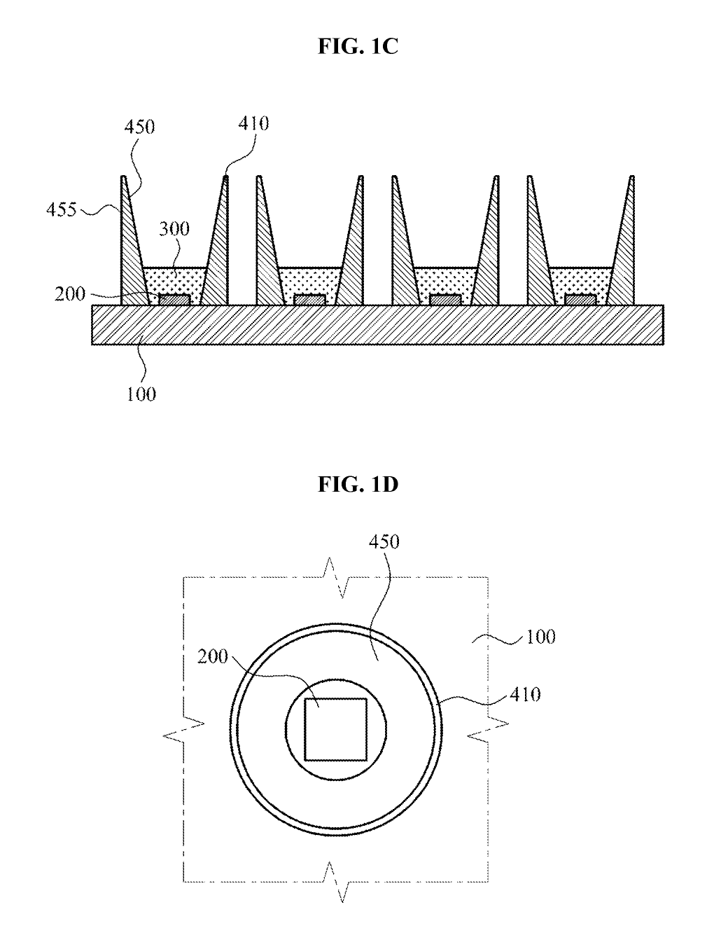

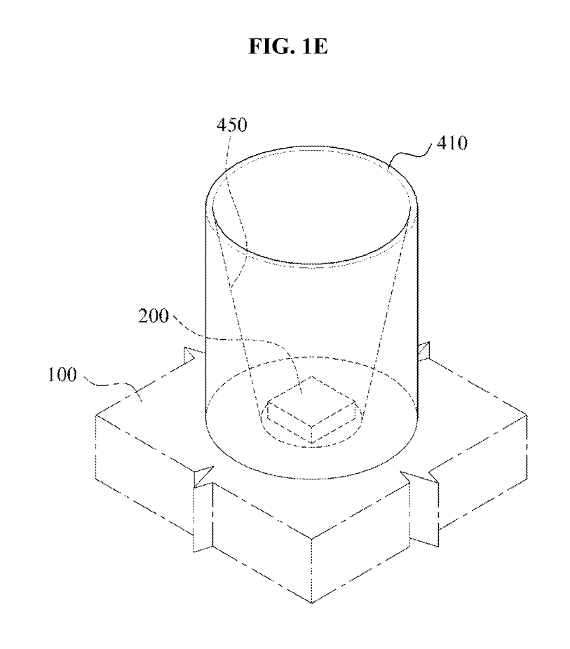

FIGS. 1A through 1C are cross-sectional views illustrating an LED module according to example embodiments. In particular, FIG. 1C is a cross-sectional view illustrating LED modules disposed in a form of an array according to example embodiments.

Referring to FIGS. 1A through 1C, the LED module may include a substrate 100, an LED 200 mounted on the substrate 100, a phosphor layer 300 disposed on the LED 200, and a first reflector 410 surrounding the LED 200. The first reflector 410 includes an inclined inner plane 450 and an outer plane 455 that is opposite the inclined inner plane. While FIGS. 1A through 1C illustrate the outer plane 455 is perpendicular to the substrate 100, example embodiments are not limited thereto and the outer plane may form a non-perpendicular angle with the substrate 100. A view angle may be adjusted (and/or affected) based on a difference between a height of the first reflector 410 and a height of the phosphor layer 300.

The substrate 100 may be manufactured using a material such as metal, a semiconductor (e.g., silicon), ceramic, and the like. The substrate 100 may be manufactured using a material having an excellent heat radiation characteristic.

The LED 200 may be mounted on the substrate 100. A scheme of mounting the LED 200 may include a flip chip bonding scheme, which may use a solder or an adhesive having a conductive characteristic. That is, the LED 200 may be flip chip bonded and mounted on the substrate 100. Also, the LED 200 may be mounted on the substrate 100 by a die bonding scheme.

According to example embodiments, when an LED module is manufactured using a chip on board (COB) scheme, the LED module may be manufactured as a flip chip on module (FCOM) in which an LED is mounted on a module substrate in a flip chip form, rather than using a wire bonding scheme for an electrical connection between the LED and the module substrate. Accordingly, when the LED is mounted to the FCOM, the LED may be mounted in a flip chip form and thus, LEDs may be mounted on the module substrate with high-density, thereby decreasing a module size.

The LED 200 will be briefly described. The LED 200 may include a first conductive semiconductor layer, an active layer, a second conductive semiconductor layer, and an electrode. The first conductive semiconductor layer may include a group III-V compound. The first conductive semiconductor layer may include gallium nitride (GaN), but example embodiments are not limited thereto.

The first conductive semiconductor layer may be n-doped. Here, n-doping indicates doping of a group V element, and an n-type impurity may include silicon (Si), germanium (Ge), selenium (Se), tellurium (Te), carbon (C), and the like. The first conductive semiconductor layer may include n-GaN. In this instance, an electron may be moved to the active layer through the first conductive semiconductor layer.

The active layer may be formed on the first conductive semiconductor layer. The active layer may be formed in a laminated structure in which a quantum barrier layer and a quantum well layer are alternately formed so that an electron and a hole may recombine and emit light. That is, the active layer may be formed to include a single quantum well or multi-quantum wells. Composition of the active layer may vary depending on a desired emission wavelength. For example, the quantum barrier layer may include GaN, and the quantum well layer may include indium gallium nitride (InGaN).

The second conductive semiconductor layer may be formed on the active layer. The second conductive semiconductor layer may include a group III-V compound. The second conductive semiconductor layer may be p-doped. Here, p-doping indicates doping of a group III element, and a p-type impurity may include magnesium (Mg), zinc (Zn), beryllium (Be), and the like. In particular, the second conductive semiconductor layer may be doped with an Mg impurity. For example, the second conductive semiconductor layer may include GaN. In this instance, a hole may be moved to the active layer through the second conductive semiconductor layer.

A transparent electrode may be formed on the second conductive semiconductor layer. The transparent electrode may be formed as a transparent metal layer such as nickel (Ni)/gold (Au) or be formed to include conductive oxide such as indium tin oxide (ITO). A p-type electrode may be formed on the transparent electrode, and an n-type electrode may be formed on the first conductive semiconductor layer. Here, the p-type electrode and the n-type electrode may be formed using various metallic materials such as titanium (Ti)/aluminum (Al), and the like.

A hole may be provided through the p-type electrode, and an electron may be provided through the n-type electrode. The provided hole and the electron may combine in the active layer to generate light energy. That is, light may be emitted from the LED 200 including the active layer, and the LED 200 may correspond to an ultraviolet LED or a blue light LED depending on a wavelength of the emitted light.

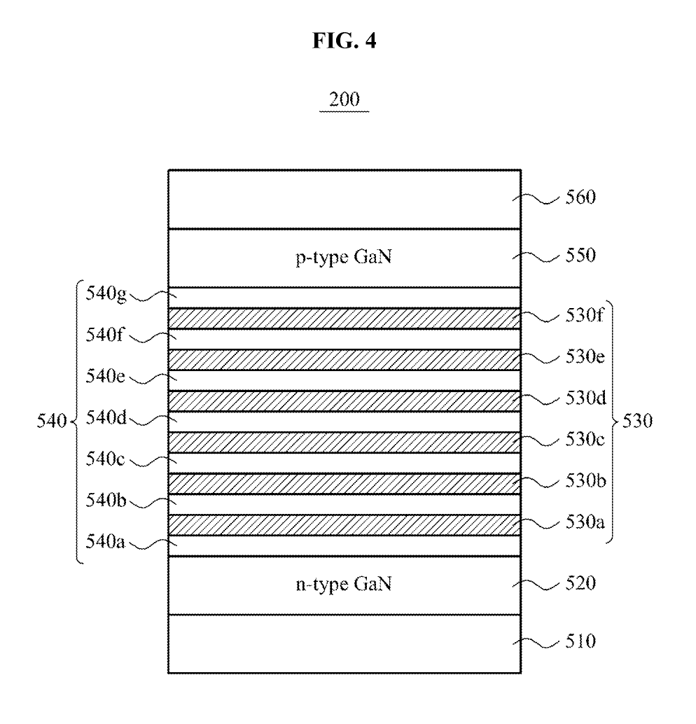

FIG. 4 is a cross-sectional view of an LED in an LED module according to example embodiments.

Referring to FIG. 4, according to example embodiments, an LED 200 may include a first semiconductor layer 520 on a lower electrode layer 520. The first semiconductor layer 520 may contain an n-type semiconductor (e.g., n-type GaN). Quantum barrier layers 530 (530a to 530f) and quantum well layers 540 (540a to 540g) may be alternately stacked on the first semiconductor layer 520. A second semiconductor layer 550 may be on the quantum barrier 530 and quantum well 540 layers. The second semiconductor layer 550 may be a p-type semiconductor (e.g., p-type GaN). A second electrode 560 may be on the second semiconductor layer 550.

Referring to FIGS. 1A through 1C, the phosphor layer 300 may surround the LED 200. Since the phosphor layer 300 surrounds the LED 200, light emitted from the LED 200 may be emitted to an external environment through the phosphor layer 300.

The phosphor layer 300 may scatter and color-convert the light emitted from the LED 200. For example, blue light emitted from the LED 200 may be converted to yellow, green, or red light through the phosphor layer 300, and white light may be emitted to the external environment.

The phosphor layer 300 may include a phosphor resin which may convert blue light to yellow, green, or red light. The phosphor layer 300 may include a host material and an active material, and may include, for example, a cerium (Ce)-activated material in an yttrium aluminum garnet (YAG) host material. A europium (Eu)-activated material included in a silicate-based host material may be used for the phosphor layer 300, but may not be limited thereto.

Phosphor particles may be uniformly (or substantially uniformly) distributed in the phosphor layer 300. Thus, light penetrating the phosphor layer 300 may be uniformly (or substantially uniformly) color-converted. Also, an uneven pattern may be formed on an upper portion of the phosphor layer 300, thereby increasing extraction efficiency of the light emitted to the external environment through the phosphor layer 300.

The phosphor layer 300 may be formed by dispensing a phosphor resin on the LED 200. A height of the phosphor layer 300 may vary depending on an amount of the phosphor resin dispensed. When a height of the first reflector 410 is fixed, a difference between the height of the first reflector 410 and the height of the phosphor layer 300 may be adjusted (and/or affected) by varying the height of the phosphor layer 300. A further description as to the foregoing will be provided later.

The first reflector 410 may surround the LED 200, and may have the inclined inner plane 450. The inclined inner plane 450 of the first reflector 410 may have a curved surface, and may be in contact with the phosphor layer 300. That is, the inner plane 450 of the first reflector 410 may be curved to reflect light emitted from the LED 200 so that the light may be emitted to the external environment. The form of the inclined inner plane 450 of the first reflector 410 may be changed based on a desired view angle.

The inclined inner plane 450 of the first reflector 410 may be coated with a reflective material or may be coated with a reflective sheet comprising the reflective material in order to improve reflection efficiency. The first reflector 410 may be formed using materials, for example, silicone, epoxy resin, and the like, but example embodiments are not limited thereto.

When different view angles are desired depending on various applications, a desired view angle may be obtained by adjusting a difference D between the height of the first reflector 410 and the height of the phosphor layer 300.

The height of the first reflector 410 may be greater than the height of the phosphor layer 300. Here, the height of the first reflector 410 and the height of the phosphor layer 300 may refer to distances from the substrate 100 to the first reflector 410 and the phosphor layer 300, respectively. The heights of the first reflector 410 and the phosphor layer 300 may be adjusted. However, the height of the first reflector 410 may be greater than the height of the phosphor layer 300.

When the desired view angle is great, the difference D between the height of the first reflector 410 and the height of the phosphor layer 300 may be small. That is, when the difference D between the height of the first reflector 410 and the height of the phosphor layer 300 is small, a size of the view angle may increase since light emitted to a side plane through the phosphor layer 300 may not be interrupted by the first reflector 410.

Conversely, when the desired view angle is small, the difference D between the height of the first reflector 410 and the height of the phosphor layer 300 may be great. That is, when the difference D between the height of the first reflector 410 and the height of the phosphor layer 300 is great, the size of the view angle may decrease since the light emitted to the side plane through the phosphor layer 300 may be reflected by the first reflector 410 and may fail to be spread widely.

When different view angles are desired depending on various applications, a desired view angle for each application may be obtained, briefly, by adjusting the difference D between the height of the first reflector 410 and the height of the phosphor layer 300. In this instance, the difference D between the height of the first reflector 410 and the height of the phosphor layer 300 may be changed by adjusting the height of the phosphor layer 300 formed by dispensing a phosphor resin in a state in which the height of the first reflector 410 is fixed to a desired (and/or predetermined) value, or may be changed by adjusting the height of the first reflector 410 in a state in which the height of the phosphor layer 300 is fixed to a desired (and/or predetermined) value. In addition, the difference D between the height of the first reflector 410 and the height of the phosphor layer 300 may be adjusted by flexibly changing both the height of the first reflector 410 and the height of the phosphor layer 300 based on the desired view angle, rather than fixing both the height of the first reflector 410 and the height of the phosphor layer 300 to the desired (and/or predetermined) values.

As shown in FIG. 1C, LEDs 200 may be disposed on the substrate 100 in a form of an array. That is, the plurality of LEDs 200 may be mounted on the substrate 100 by a COB scheme, and the first reflector 410 and the phosphor layer 300 may be formed with respect to each of the LEDs 200. In a case of the array form, the entire view angle may be adjusted by varying a view angle of light emitted from each of the LEDs 200. That is, the entire view angle in the array form may be adjusted (and/or affected) by varying a height of the phosphor layer 300 disposed on each of the LEDs 200 and thereby varying the view angle of the light emitted from respective LEDs 200. In addition, the first reflector 410 may be formed on a single chip, and may also be formed identically on each of a plurality of chips in a case of a multi-chip on which the plurality of chips are disposed.

FIGS. 1D through 1E are a top view and a perspective view illustrating a light emitting device (LED) module according to example embodiments.

Referring to FIGS. 1D through 1E, an example of the first reflector 410 having an inclined inner plane 450 and the LED 200 on the substrate 100 are shown. However, example embodiments are not limited to the shape of the first reflector 410 and LED 200 in FIGS. 1D through 1E.

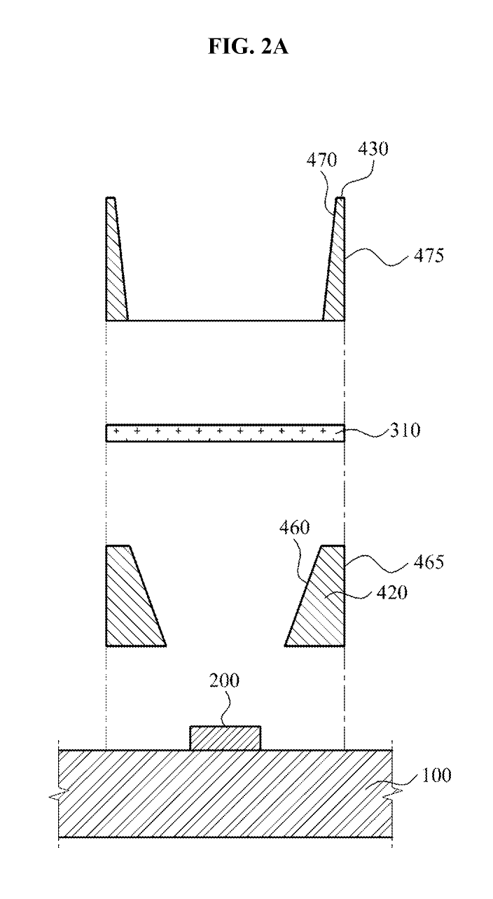

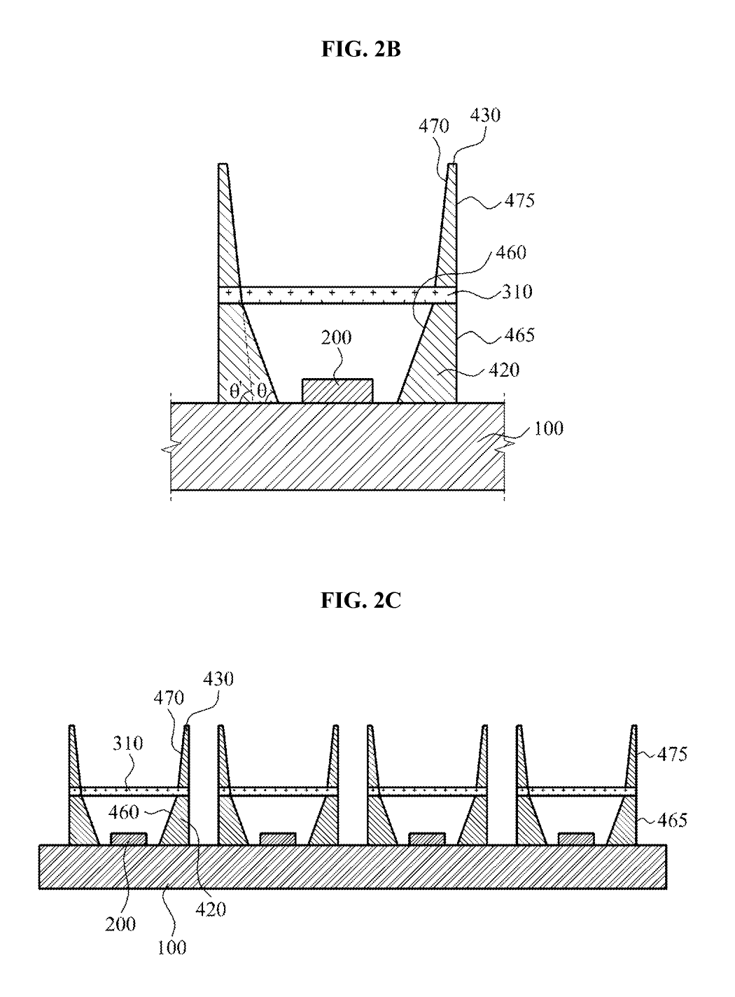

FIGS. 2A through 2C are cross-sectional views illustrating an LED module according to example embodiments.

Hereinafter, an LED module according to example embodiments will be described with reference to FIGS. 2A through 2C. In order to avoid a duplicated description, the description will focus on a configuration for obtaining a desired view angle. Similar to FIG. 1C, FIG. 2C is a cross-sectional view illustrating a plurality of LED modules disposed in a form of an array.

Referring to FIGS. 2A through 2C, the LED module may include a substrate 100, an LED 200 mounted on the substrate 100, a second reflector 420 surrounding the LED 200 and having an inclined inner plane 460, a third reflector 430 surrounding the LED 200 and having an inclined inner planes 470, and a phosphor plate 310 disposed between the second reflector 420 and the third reflector 430. The second reflector 420 includes an outer plane 465 that is opposite the inner plane 460. The third reflector 430 includes an outer plane 475 that is opposite the inner plane 475. While FIGS. 2A through 2C illustrate outer planes 460 and 475 are perpendicular to the substrate 100, example embodiments are not limited thereto. For example, the outer planes 460 and 475 may form non-perpendicular angles with the substrate 100.

A view angle may be adjusted (and/or affected) based on a height of the third reflector 430. That is, when a size of a desired view angle is relatively great, the height of the third reflector 430 may be relatively small. When the height of the third reflector 430 is relatively small, the size of the view angle may increase since light extracted to a side plane through the phosphor plate 310 may not be interrupted by the third reflector 430.

Conversely, when the size of the desired view angle is relatively small, the height of the third reflector 430 may be relatively great. That is, when the height of the third reflector 430 is relatively great, the size of the view angle may decrease since the light emitted to the side plane through the phosphor plate 310 may be reflected by the third reflector 430 and may fail to be spread widely.

Also, the view angle may be adjusted (and/or affected) based on a difference between a gradient of the inner plane 460 of the second reflector 420 and a gradient of the inner plane 470 of the third reflector 430.

When different view angles are desired depending on various applications, a desired view angle may be obtained by adjusting a difference θ′-θ between the gradient of the inner plane 460 of the second reflector 420 and the gradient of the inner plane 470 of the third reflector 430.

The gradient of the inner plane 460 of the second reflector 420 may be less than the gradient of the inner plane 470 of the third reflector 430. Here, the gradient of the inner plane 460 of the second reflector 420 and the gradient of the inner plane 470 of the third reflector 430 may refer to angles by which the inner plane 460 of the second reflector 420 and the inner plane 470 of the third reflector 430 are inclined on the basis of the substrate 100, and may be denoted as θ′ and θ, respectively, as shown in FIG. 2B. Also, a relatively great gradient may indicate that an angle of inclination on the basis of the substrate 100 is relatively great.

When a size of a desired view angle is relatively small, the gradient of the inner plane 460 of the second reflector 420 may be lesser than the gradient of the inner plane 470 of the third reflector 430. That is, the size of the view angle may decrease since light reflected by the second reflector 420 may be reflected once more by the third reflector 430, and the light spreading to a size plane may be interrupted.

Conversely, when the size of the desired view angle is relatively great, the gradient of the inner plane 460 of the second reflector 420 may be greater than the gradient of the inner plane 470 of the third reflector 430. That is, the size of the view angle may increase since the light reflected by the second reflector 420 may not be interrupted by the third reflector 430, and may spread to the side plane.

Therefore, when different view angles are desired depending on various applications, a desired view angle for each application may be obtained by adjusting the gradient of the inner plane 460 of the second reflector 420 and the gradient of the inner plane 470 of the third reflector 430.

Also, the phosphor plate 310 may be disposed between the second reflector 420 and the third reflector 430 to adjust Commission International de l'Eclairage (CIE) color coordinates and a Correlated Color Temperature (CCT) of light emitted to an external environment based on a correlation between the LED 200 and the phosphor plate 310. Luminance of the light extracted to the external environment may be changed by adjusting thickness and density of the phosphor plate 310. That is, in a case where an identical LED 200 is used, the luminance may be adjusted by changing the phosphor plate 310 only.

Furthermore, since a single module may be manufactured by separately assembling each reflector, a phosphor layer, or a phosphor plate, each element may be optimized for desired specifications of a final product. That is, manufacturing efficiency may be improved by flexibly optimizing and assembling elements when the specifications of the final project are changed. Also, when luminance declines as a product is used over a long period time, luminance of an identical quality may be obtained by replacing the phosphor plate 310 only.

Therefore, a view angle and product specifications may vary depending on various applications of an LED for lighting. According to example embodiments, there may be provided an LED module applied flexibly depending on the changed factors.

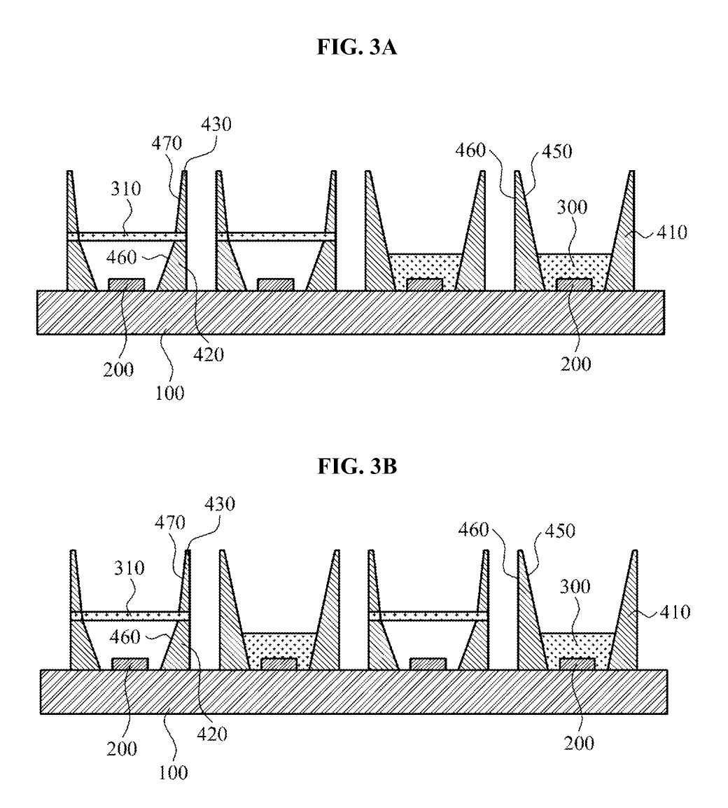

FIGS. 3A and 3B are cross-sectional views illustrating an LED module according to example embodiments. In order to avoid a duplicated description, the description will focus on differences between FIGS. 3A, 3B, and FIGS. 1A to 1C and FIGS. 2A to 2C.

Referring to FIGS. 3A and 3B, an LED module according to example embodiments may include a substrate 100 and a plurality of LEDs 200 mounted on the substrate 100. Some of the plurality of LEDs 200 may be surrounded by a plurality of the first reflectors 410 and covered by a plurality of the phosphor layers 300, respectively, as described previously with respect to FIGS. 1A to 1C. While others of the plurality of LEDs 200 may be surrounded by a plurality of the second reflectors 420, respectively, as described previously with respect to FIGS. 2A to 2C. A plurality of phosphor plates 310 may be disposed between the plurality of second reflectors 420 and a plurality of third reflectors 430.

While FIG. 3A illustrates a LED module where the LEDs 200 surrounded by first reflectors 410 are adjacent to each other and the LEDs surrounded by second reflectors 420 are adjacent to each other, example embodiments are not limited thereto. For example, FIG. 3B illustrates a LED module where the LEDs 200 surrounded by first reflectors 410 are alternately arranged with LEDs surrounded by second reflectors 420. Alternatively, the LEDs 200 surrounded by first reflectors 410 and the LEDs 200 surrounded by second reflectors 420 may have a block arrangement (e.g., AABBBAABBBAA) or a random arrangement.

While some example embodiments have been particularly shown and described, it will be understood by one of ordinary skill in the art that variations in form and detail may be made therein without departing from the spirit and scope of the claims.

What is claimed is:

1. A light emitting device (LED) module, comprising:
a substrate;
an LED on the substrate;
a phosphor layer on the LED; and
a first reflector surrounding the LED,
the first reflector having an inclined inner plane, and
the first reflector being configured to adjust a view angle of the LED based on a difference between a height of the first reflector and a height of the phosphor layer.

2. The LED module of claim 1, wherein the inclined inner plane of the first reflector is a curved surface.

3. The LED module of claim 1, wherein the height of the first reflector is greater than the height of the phosphor layer.

4. The LED module of claim 1, wherein the phosphor layer contains a phosphor resin.

5. The LED module of claim 1, wherein the LED is connected to the substrate using one of a flip chip bonding scheme and a die bonding scheme.

6. A light emitting device (LED) module, comprising:
a substrate;
a LED on the substrate;
a first reflector and a second reflector surrounding the LED from a plan view,
the first reflector and the second reflector having inclined inner planes, and
the second reflector being configured to adjust a view angle of the LED based on a height of the second reflector; and
a phosphor plate between the first reflector and the second reflector.

7. The LED module of claim 6, wherein a gradient of the inner plane of the first reflector is different from a gradient of the inner plane of the second reflector.

8. The LED module of claim 7, wherein the gradient of the inner plane of the first reflector is less than the gradient of the inner plane of the second reflector.

9. The LED module of claim 7, wherein the inclined inner planes of the first reflector and the second reflector have curved surfaces.

10. The LED module of claim 6, wherein the LED is connected to the substrate using one of a flip chip bonding scheme and a die bonding scheme.

11. A light emitting device (LED) module, comprising:
a substrate;
a LED on the substrate;
a first reflector on the substrate,
the first reflector surrounding the LED from a plan view,
the first reflector having a width at a middle portion of the reflector between an outer plane and an inclined inner plane that is smaller than a width at a bottom portion of the reflector between the outer plane and the inclined inner plane; and
a phosphor structure contacting the first reflector.

12. The LED module of claim 11, wherein
the phosphor structure is a phosphor layer on the LED,
the phosphor layer contacts the inclined inner plane of the first reflector,
a height of the phosphor layer is less than a height of the first reflector, and
the inclined inner plane of the first reflector has a curved surface.

13. The LED module of claim 11, further comprising:
a second reflector on the phosphor structure, wherein
the second reflector surrounds the LED from the plan view,
the second reflector has an inclined inner plane, and
a gradient of the inclined inner plane of the second reflector is different from a gradient of the inclined inner plane of the first reflector.

14. The LED module of claim 11, wherein
a plurality of the LEDs are on the substrate,
a plurality of the first reflectors surround the plurality of LEDs from the plan view, respectively, and
a plurality of the phosphor structures contact the plurality of first reflectors respectively.

15. The LED module of claim 11, wherein the LED is connected to the substrate using one of a flip chip bonding scheme and a die bonding scheme.

16. The LED module of claim 1, wherein
the first reflector contacts the phosphor layer, and
a width at a top portion of the first reflector is smaller than a width at a bottom portion of the first reflector.
